(19) United States
(12) Patent Application Publication
(10) Pub. No.: US 2009/0096650 A1
(43) Pub. Date: Apr. 16, 2009

(54) Methods and systems for continuous-time digital modulation

(76) Inventor: Yannis Tsividis, New York, NY (US)

Correspondence Address: WilmerHale/Columbia University, 399 PARK AVENUE, NEW YORK, NY, 10022, US

(21) Appl. No.: 11/792,354

(22) PCT Filed: Dec. 6, 2005
(86) PCT No.: PCT/US05/44534

§ 371 Date: Aug. 27, 2008

Related U.S. Application Data
(60) Provisional application No. 60/633,747, filed on Dec. 7, 2004.

(51) Int. Cl. H03M 1/12

(52) U.S. Cl. 341/155

(57) ABSTRACT

Methods and systems for modulating (508) a radio frequency signal by a continuous-time signal are presented. More particularly, techniques and systems for converting an analog signal (202) to a continuous-time digital signal and using this continuous-time digital signal (204) to modulate (508) a radio-frequency signal in continuous-time are provided. This may be accomplished through the use of a continuous-time analog-to-digital converter (204). When modulating the continuous-time digital signal (508), various kinds of modulation may be utilized such as amplitude, frequency, phase, and/or any combination of the three (508). In some embodiments, a digital signal processor may be added to the system to process the continuous-time digital signal (506).

### CROSS-REFERENCE TO RELATED APPLICATIONS

This application claims the benefit of U.S. Provisional Patent Application No. 60/633,747, filed Dec. 7, 2004, which is hereby incorporated herein by reference in its entirety.

### BACKGROUND OF THE INVENTION

The present invention relates to continuous-time signals. More particularly, this invention relates to the modulation of continuous-time signals.

Modulation is the process of adding information to a carrier signal, so that the information signal can be transmitted at a given frequency. Generally, the amplitude, frequency, and phase of a carrier signal can be modulated to place information on the carrier signal. In some cases, when a digital radio-frequency (RF) modulator is used to modulate a carrier signal, an analog-to-digital conversion (ADC) of an analog signal to be modulated needs to be performed. This ADC typically requires a clock for sampling the input analog signal. U.S. Pat. Nos. 4,403,197 and 4,580,111 describe modulation techniques that are performed in discrete-time using a clock for sampling an input analog signal. However, such sampling may result in aliasing of the signal and quantization error in the base band. It would therefore be desirable to minimize the effects of aliasing and quantization error in the base band signal.

### SUMMARY OF THE INVENTION

Methods and systems for modulating a continuous-time signal are presented. More particularly, the present invention provides techniques and systems for converting an analog signal to a continuous-time digital signal, and using this signal to modulate a radio frequency signal, in continuous-time. This may be accomplished through the use of a continuous-time analog-to-digital converter. When modulating the radio frequency signal with the continuous-time digital signal, various kinds of modulation may be utilized such as amplitude, frequency, phase, and/or any combination of the three. In some embodiments, a digital signal processor may be added to the system to process the continuous-time digital signal.

In accordance with the present invention, certain embodiments feature a continuous-time analog-to-digital converter that simultaneously produces two or more continuous-time digital signals, and a digital input signal modulator coupled to the continuous-time analog-to-digital converter that produces a modulated output in response to the two or more continuous-time digital signals.

Further in accordance with the present invention, certain embodiments feature a method for comparing in continuous-time the input signal to two or more thresholds, producing simultaneously two or more intermediate signals based on the two or more thresholds, encoding the two or more intermediate signals into a continuous-time digital output, and producing a modulated signal based on the values of the continuous-time digital output.

Still further in accordance with the present invention, certain embodiments feature a technique for simultaneously producing two or more continuous-time digital signals in response to the input signal, and a technique for receiving and modulating the two or more of continuous-time digital signals and producing a modulated output.

### BRIEF DESCRIPTION OF THE DRAWINGS

The above and other advantages of the present invention will be apparent upon consideration of the following detailed description, taken in conjunction with accompanying drawings, in which like reference characters refer to like parts throughout, and in which:

FIG. 1 is a graph representing a continuous-time Analog-to-Digital conversion (ADC) in accordance with certain embodiments of the present invention;

FIG. 2 is a block diagram representing an un-clocked ADC modulation system in accordance with certain embodiments of the present invention;

FIG. 3 is a block diagram representing a detailed view of the un-clocked ADC system in accordance with certain embodiments of the present invention;

FIG. 4 is a block diagram representing a detailed view of a modulator in accordance with certain embodiments of the present invention;

FIG. 5 is a block diagram representing an un-clocked ADC modulation system with digital signal processing in accordance with certain embodiments of the present invention; and

FIG. 6 is a block diagram representing a detailed view of a digital signal processor in accordance with certain embodiments of the present invention.

### DETAILED DESCRIPTION OF THE INVENTION

As stated above, the present invention relates to the modulation of continuous-time signals. More particularly, this invention relates to techniques and systems for converting an analog signal to a digital signal and modulating the digital signal in continuous-time. Continuous-time digital modulation may be accomplished in accordance with the present invention by digitizing the analog input signal without sampling in time (i.e., without using a clock to digitize the analog input signal). By implementing a digitizing technique without using sampling, aliasing of the signal can be avoided and introduction of quantization error into the base band may be reduced.

In certain embodiments of the present invention, a set of data points (tᵢ, xᵢ) may be used to describe a continuous-time digital signal, where xᵢ represents an absolute amplitude value, and tᵢ represents the time when the amplitude value was met or passed. In some embodiments of the present invention, it may be desirable to represent changes in amplitude (i.e., relative amplitude values) rather than absolute amplitude values so that a type of delta modulation signal may be implemented.

The quantized and digitized information related to an input analog signal (e.g., the set of data points) may be stored in a memory medium (such as a magnetic medium, optical medium, or any other suitable storage medium) for later transmission and/or processing.

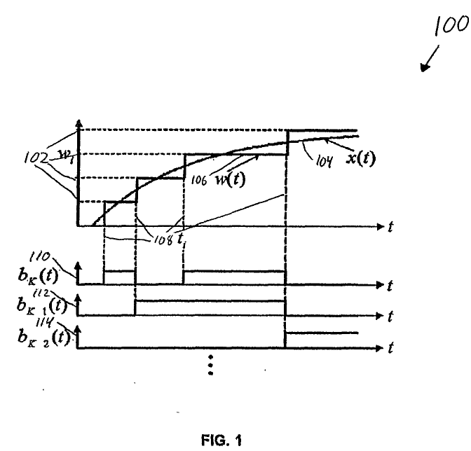

FIG. 1 illustrates a graph 100 showing the quantization and digitization of an analog signal x(t) 104 into a quantized continuous-time signal w(t) 106 in accordance with certain embodiments of the present invention. As shown, graph 100 contains level lines wᵢ 102, input signal x(t) 104, quantized signal w(t) 106, and time points tᵢ 108. Level lines wᵢ 102 represent amplitude values that mark thresholds for quantized signal w(t) 106. Quantized signal w(t) 106 results when input signal x(t) 104 is approximated to level lines wᵢ 102. As illustrated, input signal x(t) 104 is approximated to the next higher level line when input signal 104 x(t) is more than halfway between two level lines wᵢ 102. Likewise, if the input signal falls below the halfway point between level lines wᵢ 102, then quantized signal w(t) 106 drops to the lower level line. Other suitable transition points may additionally and/or alternatively be used.

As illustrated in FIG. 1, digital bits 110, 112, and 114 correspond to level lines wᵢ 102 and the time periods tᵢ 108. Each level line corresponds to a bit pattern comprising bit bₖ(t) 110, bit bₖ₁(t) 112, bit bₖ₂(t) 114 and so on, where bit bₖ(t) 110 is the least significant bit and bit bₖ₂(t) 114, for example, is the most significant bit. As can be seen, the transitions between the bit patterns may occur at any time rather than at predetermined instants of time. The ability to transition at any point in time, rather than at specified time points, makes the digital representation a continuous-time digital representation of input signal x(t) 104. Although three bits are shown in the continuous-time signal, it should be understood that the quantized signal w(t) 106 may include any number of bits. Other embodiments for representing an input analog signal with a quantized and digitized continuous-time signal may also be used.

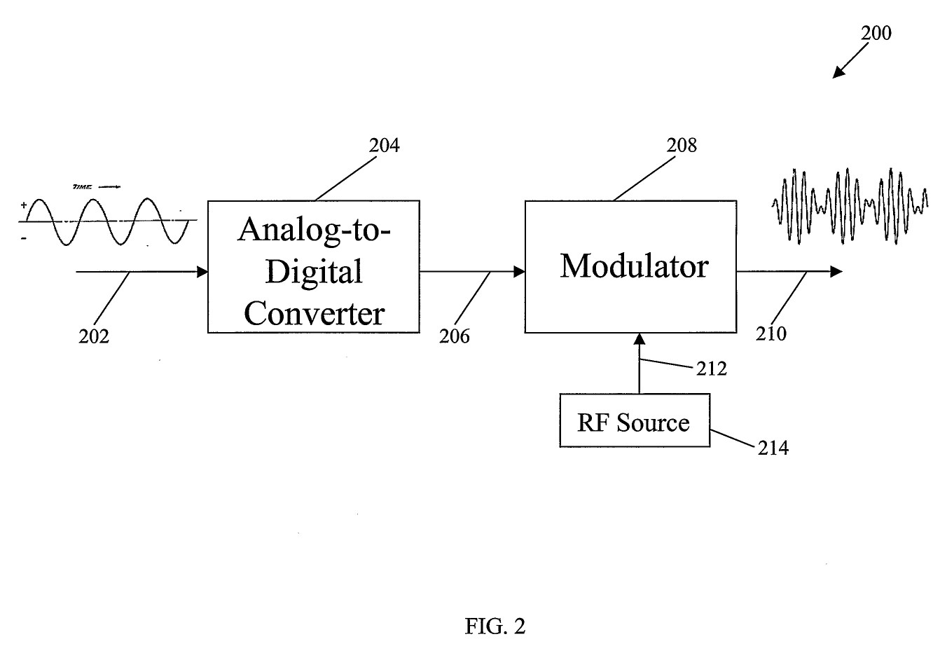

As shown in FIG. 2, a block diagram of a continuous-time digital modulator system 200 is illustrated in accordance with certain embodiments of the present invention. System 200 includes an analog input 202, a continuous-time Analog-to-Digital (A/D) converter 204, a continuous-time digital signal 206, a digital modulator 208, and a modulated output 210. In system 200, analog input 202 is converted into digital signal 206 by continuous-time A/D converter 204 as described above in connection with FIG. 1. Modulator 208 uses the continuous-time digital signal 206 to modulate a radio frequency signal 212 from RF source 214, in order to form modulated output 210.

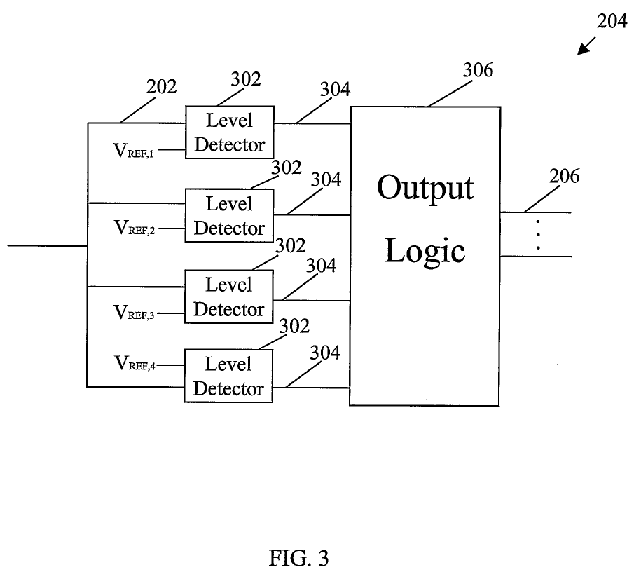

FIG. 3 illustrates an embodiment of A/D converter 204 in more detail. As shown, A/D converter 204 may include an analog input 202, level detectors 302, level outputs 304, an output logic device 306, and a continuous-time digital signal 206. As shown, a plurality of level detectors 302 compare input signal 202 to quantization level thresholds provided by reference voltages V_{REF,1}, V_{REF,2}, V_{REF,3}, and V_{REF,4}. A level detector may be implemented using an operational amplifier as a comparator or with any other suitable device. Level outputs 304 encode the level values from level detectors 302. Output logic device 306 converts level outputs 304 into a binary digital signal 206. Output logic device 306 may be implemented by using a look-up table or other suitable logic.

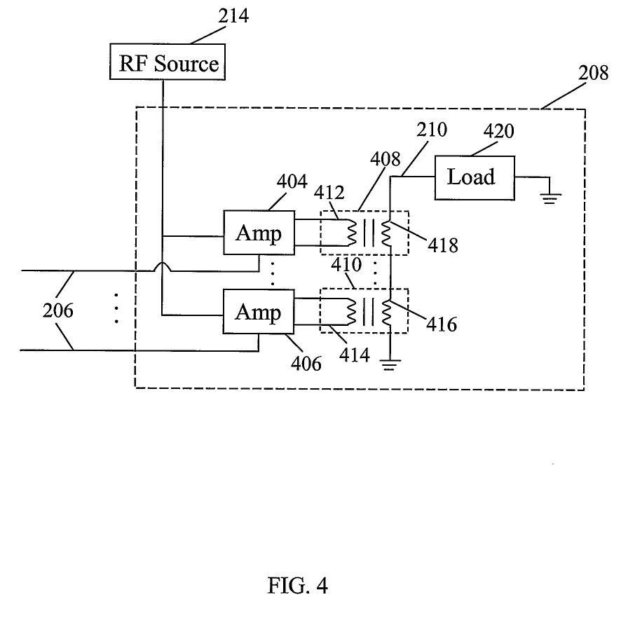

FIG. 4 illustrates in more detail a modulator 208 in accordance with certain embodiments of the present invention. Modulator 208 includes a continuous-time digital signal 206, a radio frequency (RF) source 402, a plurality of power amplifiers 404 and 406, a plurality of transformers 408 and 410, a load 420, and modulated output 210. In modulator 208, power amplifiers 404 and 406 are used to modulate RF source 214 according to continuous-time digital signal 206. The modulation may occur by using the binary continuous-time digital signal 206 to turn on and turn off power amplifiers 404 and 406. The modulation may be amplitude modulation with the switching of power amplifiers 404 and 406 changing the amplitude of the modulated signal that is outputted by modulator 208.

Each power amplifier may be identical to other power amplifiers or different from them. For example, power amplifiers 404 and 406 may be equally weighted, binary weighted, or a mixture of the two. The power amplifiers may be implemented using any suitable technologies, such as metal-oxide-semiconductor field effect transistors (MOSFET), insulated gate bipolar transistors (IGBT), bipolar junction transistors (BJT), MOS-controlled thyristors (MCT), gate-turn-off thyristors (GTO), and/or any other suitable technologies.

As shown, modulated output 210 is fed to load 420, which can be an antenna, through transformers 408 and 410. Each of transformers 408 and 410 may include a corresponding primary 412 or 414 and a corresponding secondary 416 or 418. The secondaries 418 and 416 may each act as an independent signal source so that the signals provided by the transformers can additively combine with one another to form modulated output 210. Although only two amplifiers 404 and 406 and two transformers 408 and 410 are shown in FIG. 4, and suitable number of these devices may be used.

In some embodiments, an RF phase shifter may be placed before one or more of power amplifiers 404 and 406 to selectively adjust the phase of the signals inputted to amplifiers 404 and 406 from RF source 402. The phase changes of the RF phase shifters can be digitally controlled and may be controlled by continuous-time digital signal 206.

Similarly, in certain embodiments, the frequency of the RF source may be adjusted by digital signal 206 to permit modulation of the frequency of the RF source signal. In some embodiments, multiple aspects of the RF source are adjusted, such as the frequency, phase, and amplitude of the signal. Also varying schemes of modulation such as amplitude-shift keying, phase-shift keying, frequency-shift keying, amplitude modulation, frequency modulation, or any applicable combination may be used for modulating and transmitting a signal.

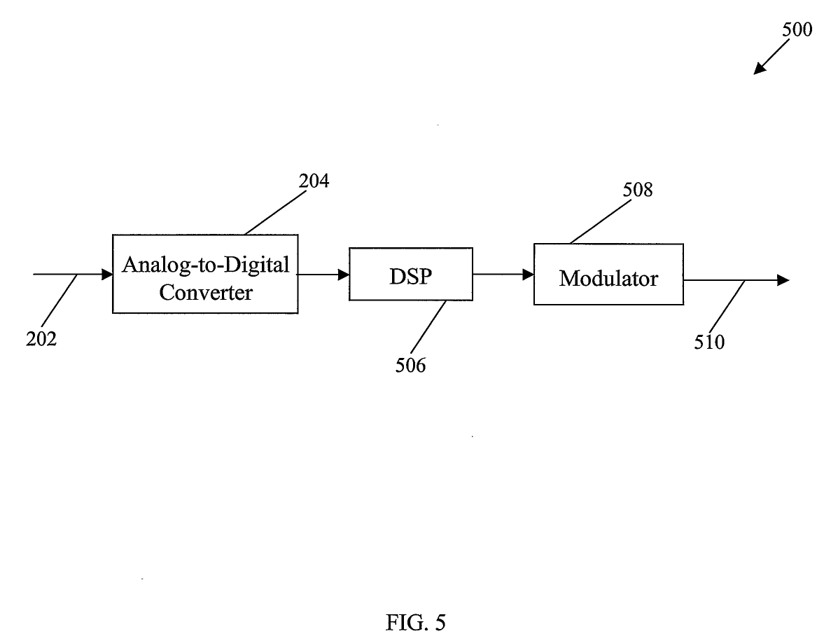

FIG. 5 illustrates a signal modulation system 500 with a continuous-time digital signal processor (DSP) 506 before a modulator 508 in accordance with certain embodiments of the present invention. The addition of continuous-time DSP 506 may allow manipulation and adjustment of the signal before modulation. Digital signal processing can be used to change the characteristics of the signal. For example, digital signal processing may be used to implement digital filters such as a low-pass filter, a high-pass filter, a notch filter, a comb filter, a smoothing filter, or any other desirable filter. After the digital processing is complete, modulator 508 receives the output of continuous-time DSP 506 and can use the digital signal, as described above, to modulate the digital signal onto a carrier frequency and output a processed modulated signal 510.

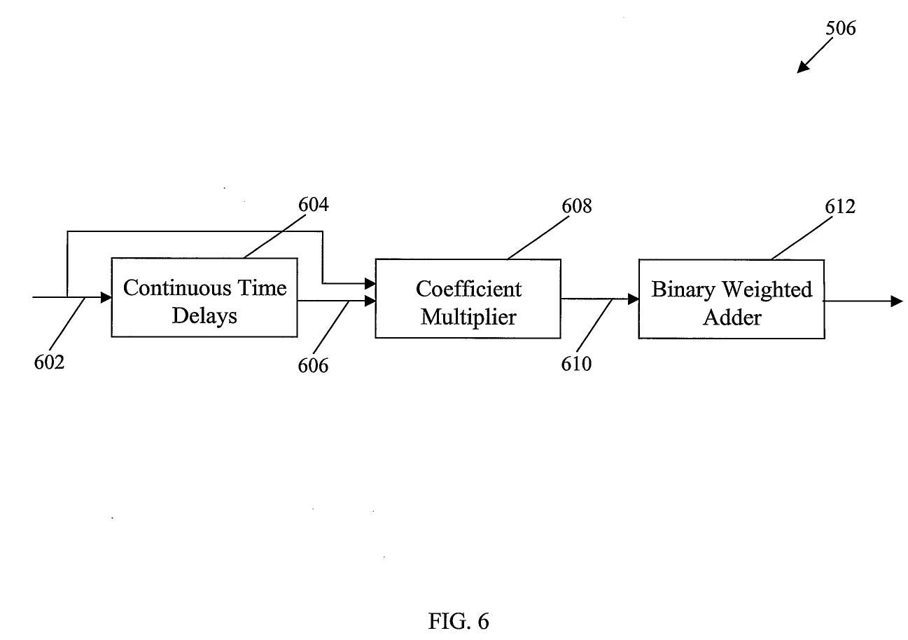

FIG. 6 illustrates a more detailed view of a continuous-time DSP 506 in accordance with certain embodiments of the present invention. Continuous-time DSP 506 includes a continuous-time DSP input 602, a continuous-time delay 604, a delayed signal 606, a coefficient multiplier 608, a delayed multiplied signal 610, and a binary-weighted adder 612. Binary-weighted adder 612 may be optionally replaced with a non-binary-weighted adder depending on whether output logic device 306 is used to encode the level value signals as binary digital signals.

As shown, continuous-time delay 604 receives continuous-time DSP input 602 and outputs delayed signal 606 along with the original continuous-time DSP input 602 to the coefficient multiplier 608. In some embodiments, continuous-time delay 604 may include one set of output signals corresponding to delayed signal 606. Delayed signal 606 and continuous-time DSP input 602 may be multiplied with varying coefficients in coefficient multiplier 608. The coefficients may correspond to a transfer function and may be set to implement functions, such as a low-pass filter. Delayed multiplied signal 610 from coefficient multiplier 608 may then be inputted into binary-weighted adder 612, which may perform a weighted summation with respect to the relative significance of the bits within delayed multiplied signal 610 obtained from the A/D conversion.

In continuous-time delay 604, each bit of continuous-time DSP input 602 may be delayed by a time period T. In some embodiments, continuous-time delay 604 comprises a cascade of logic inverters, with one or more coupled with load capacitances matched to the inverter's current drive capability to produce a specified switching time. The delay provided by the logic inverters can be set to a precise value by making the inverter's current drive capability adjustable and locking the inverter's responses to an external clock.

The operation of coefficient multiplier 608 may be illustrated using an example involving a continuous-time DSP implementing an echo filter. In such an implementation, continuous-time DSP input 602 and delayed signal 606 may be passed to coefficient multiplier 608. Continuous-time DSP input 602 may then be multiplied by one or more coefficients C_{A}, and delayed signal 606 may be multiplied by one or more coefficients C_{B}. This “multiplication” may be performed using AND gates or a suitable substitute. Coefficient C_{A}may include three bits, C₁, C₂ and C₃ and coefficient C_{B} may include three bits Ĉ₁, Ĉ₂ and Ĉ₃. For each bit in input signal 602, coefficient multiplier 608 may produce six bits of data. For example, if the most significant bit (MSB) from continuous-time DSP input 602 is called D2, the resulting logical equation is C₁·D2, C₂·D2, C₃·D2, Ĉ₁·D²2, Ĉ₂·D²2 and Ĉ₃·D²2, where D2 is continuous-time DSP input 602, and D²2 is the delayed signal 606.

This data may then be sent to binary-weighted adder 612 which sums the resulting bits of data in one or more summing stages. The one or more summing stages may include adders, each of which adds the delayed signal 606 products to the continuous-time DSP input 602 products for a particular bit to produce an intermediate sum.

In general, the concepts this example represents can readily be extended to more delays, coefficients, and bits. In addition, although the above example is implemented using a non-recursive structure, the technique described can be extended to include filters with feedback loops. When feedback loops are present, the output of the continuous-time DSP may be processed in a manner similar to that described above and may be fed back to an internal point in the processor. may be processed in a manner similar to that described above and may be fed back to an internal point in the processor.

As mentioned above, a continuous-time DSP may use a transfer function to modify an input signal. A general transfer function can be developed where the delays are represented by e^{-sT}, in which s is the Laplace transform variable and T is the continuous-time delay between taps. Thus, in the case of integer n, where N is the number of delays in continuous-time DSP 506, each continuous-time bit may be processed by a transfer function of the form:

$$H ( {e}^{sT} ) = {\sum }_{n = 0}^{N} {c}_{n} {e}^{- n sT} \qquad ( 1 )$$

Continuous-time DSP input 602 may be represented as a binary-weighted sum of individual bits, each of which is processed by transfer function (1). The binary-weighted sum formed by binary-weighted adder 612 therefore corresponds to continuous-time DSP input 602 processed by the same transfer function (1). The transfer function (1) may correspond to that of a classical analog transmission-line filter and may be identical to the corresponding transfer function H(z) of a conventional digital filter.

Substituting jω for s in transfer function (1) shows that the frequency response is periodic, with a period of 2π/T. Because the continuous-time DSP 506 does not use sampling in time, there should be no aliasing in the filtered output. For example, an input at a frequency ω may produce an output at a frequency ω, regardless of the value of ω.

Although the present invention has been described and illustrated in the foregoing exemplary embodiments, it is understood that the present disclosure has been made only by way of example, and that numerous changes in the details of implementation of the invention may be made without departing from the spirit and scope of the invention, which is limited only by the claims which follow.

What is claimed is:

1. An apparatus for modulating an input signal, comprising:
a continuous-time analog-to-digital converter that simultaneously produces two or more continuous-time digital signals; and
a digital input signal modulator coupled to the continuous-time analog-to-digital converter that produces a modulated output in response to the two or more continuous-time digital signals.

2. The apparatus of claim 1, wherein the continuous-time analog-to-digital converter further comprises an output logic device that encodes the two or more continuous-time digital signals.

3. The apparatus of claim 2, wherein the output logic device produces continuous-time binary digital signals.

4. The apparatus of claim 1, further comprising:
a power amplifier controlled by the two or more of continuous-time digital signals; and
a RF source coupled to the power amplifier.

5. The apparatus of claim 1, further comprising a digital signal processor coupled between the continuous-time analog-to-digital converter and the digital input signal modulator.

6. The apparatus of claim 1, wherein the continuous-time analog-to-digital converter includes two or more level detectors that each compare the input signal to two or more thresholds to simultaneously produce two or more continuous-time digital signals.

7. A method for modulating an input signal, comprising:
comparing in continuous-time the input signal to two or more thresholds;
producing simultaneously two or more intermediate signals based on the two or more thresholds;
encoding the two or more intermediate signals into a continuous-time digital output; and
producing a modulated signal based on the values of the continuous-time digital output.

8. The method of claim 7, wherein the continuous-time digital output is a binary based continuous-time digital signal.

9. The method of claim 7, wherein the two or more intermediate signals are produced using a comparator.

10. The method of claim 7, further comprising processing the continuous-time digital output.

11. The method of claim 10, wherein the processing is implemented through a digital signal processor.

12. The method of claim 7, wherein producing a modulated signal involves frequency-shift keying.

13. The method of claim 7, wherein comparing in continuous-time the input signal includes using two or more level detectors.

14. An apparatus for modulating an input signal, comprising:
a means for simultaneously producing two or more continuous-time digital signals in response to the input signal; and
a means for receiving and modulating the two or more of continuous-time digital signals and producing a modulated output.

15. The apparatus of claim 14, wherein the means for converting also encodes an intermediate signal to produce the two or more continuous-time digital signals.

16. The apparatus of claim 15, wherein the two or more continuous-time digital signals are continuous-time binary digital signals.

17. The apparatus of claim 14, wherein the means for modulating comprises:
a means for amplifying that is controlled by the two or more continuous-time digital signals; and
a means for producing an RF signal that is coupled to the means for amplifying.

18. The apparatus of claim 14, further comprising a means for digital signal processing coupled between the means for converting and the means for modulating.

19. The apparatus of claim 14, wherein the means for simultaneously producing includes two or more level detectors.
